(19) United States
(12) Patent Application Publication
(10) Pub. No.: US 2025/0194231 A1
(43) Pub. Date: Jun. 12, 2025

(54) SEMICONDUCTOR DEVICE

(71) Applicant: DB HiTek Co., Ltd., Seoul (KR)

(72) Inventors: Won Kook CHO, Bucheon-si (KR); Myeong Bum PYUN, Bucheon-si (KR)

(73) Assignee: DB HiTek Co., Ltd., Seoul (KR)

(21) Appl. No.: 18/421,186

(22) Filed: Jan. 24, 2024

(30) Foreign Application Priority Data
Dec. 11, 2023 (KR) 10-2023-0178517

(51) Int. Cl. H01L 27/06

(52) U.S. Cl. CPC H10D 84/811

(57) ABSTRACT

A semiconductor device comprising: a substrate, an active cell region comprising a first active region including a recessed region and a second active region on the substrate, an edge terminal region surrounding the active cell region on the substrate, a first peripheral region comprising a first region within the recessed region and a second region disposed between the first active region and the edge terminal region on the substrate, a second peripheral region disposed between the second active region and the edge terminal region, and a first body diode region extending from the second region of the first peripheral region to a portion of the first active region.

### CROSS-REFERENCE TO RELATED APPLICATION

This application claims priority under 35 U.S.C § 119 to Korean Patent Application No. 10-2023-0178517 filed on Dec. 11, 2023, in the Korean Intellectual Property Office, the entire contents of which are hereby incorporated by reference.

### TECHNICAL FIELD

The disclosure relates to a semiconductor device, and more particularly, to a high voltage semiconductor device including a body diode.

### BACKGROUND

The contents set forth in this section merely provide background information on the present embodiments and do not constitute prior art.

When a semiconductor device operates as a switch, a reverse current exceeding the rated value may instantaneously flow through a body diode included in the semiconductor device. The reverse current may flow in the active cell region and the edge terminal region of the semiconductor device, and the reverse current in the edge terminal region may flow through the body diode in the peripheral region. The body diode must be able to accommodate the amount of reverse current.

Meanwhile, as the chip size increases, the amount of reverse current increases as well. Compared to smaller-sized chips, the area occupied by the body diode in the peripheral region of a relatively large-sized chip may be reduced. As the area occupied by the body diode decreases, its ability to accommodate the amount of reverse current decreases, thereby deteriorating the reverse recovery characteristics.

Therefore, there is a need for a body diode structure in a peripheral region that can accommodate the amount of reverse current.

The description set forth in the background section should not be assumed to be prior art merely because it is set forth in the background section. The background section may describe aspects or embodiments of the disclosure.

### SUMMARY

It is an object of the present disclosure to provide a semiconductor device including a body diode structure in a peripheral region that can accommodate the amount of reverse current.

The objects of the present disclosure are not limited to the objects mentioned above, and other objects and advantages of the present disclosure that have not been mentioned can be understood by the following description and will be more clearly understood by the embodiments of the present disclosure. Further, it will be readily appreciated that the objects and advantages of the present disclosure may be realized by the means set forth in the claims and combinations thereof.

The semiconductor device of the present disclosure can increase the capacity of the reverse current and thus secure reverse recovery characteristics by including a body diode structure in a peripheral region that can accommodate the amount of reverse current.

Further, the semiconductor device of the present disclosure can increase the capacity of the reverse current by improving the body diode structure in the peripheral region, and can thus reduce the possibility of burnt occurrences.

According to some aspects of the disclosure, a semiconductor device includes; a substrate, an active cell region comprising a first active region including a recessed region and a second active region on the substrate; an edge terminal region surrounding the active cell region on the substrate, a first peripheral region comprising a first region within the recessed region and a second region disposed between the first active region and the edge terminal region on the substrate, a second peripheral region disposed between the second active region and the edge terminal region, and a first body diode region extending from the second region of the first peripheral region to a portion of the first active region, wherein the first body diode region comprises, a first peripheral body diode region disposed in the second region, and a second peripheral body diode region extending from the first peripheral body diode region and extending below a first gate electrode disposed on the substrate in the first active region.

According to some aspects, a first pillar structure disposed within the substrate, disposed over a portion of the second region and the first active region, and disposed below the first body diode region; and a second pillar structure disposed within the substrate and disposed to be spaced apart from the first pillar structure in the first active region, wherein the first pillar structure comprises: a first pillar region extending into the substrate from the first peripheral body diode region in the second region; and a second pillar region extending into the substrate from the second peripheral body diode region in the first active region, and the second pillar structure extends into the substrate from a first body region below a second gate electrode disposed on the substrate in the first active region.

According to some aspects, the first peripheral body diode region extends on the first pillar structure, and the second peripheral body diode region extends between the first gate electrode and the first pillar structure.

According to some aspects, the first pillar structure further comprises a third pillar region disposed between the first pillar region and the second pillar region below the first body diode region, and connecting an upper part of the first pillar region and an upper part of the second pillar region.

According to some aspects, the first body region and the first body diode region are spaced apart from each other, and the first body region is spaced apart from a second body region that is disposed within the substrate in the first active region and disposed below the second gate electrode.

According to some aspects, the second region comprises, a first sub-region extending in a first direction and disposed between the first active region and the edge terminal region, a second sub-region extending in a second direction intersecting the first direction, and being between the first region and the edge terminal region, and a third sub-region extending in the second direction, and disposed between the first sub-region and the second sub-region and between the first active region and the edge terminal region, and wherein the first body diode region extends from the third sub-region of the second region to a portion of the first active region, and the first peripheral body diode region is disposed in the third sub-region.

According to some aspects, the third sub-region does not overlap the first region along the first direction.

According to some aspects, the first region protrudes along a first direction from the second region, and the second peripheral body diode region extends to a distal end of the first region.

According to some aspects, a second body diode region extending from the second peripheral region to a portion of the second active region.

According to some aspects of the disclosure, a semiconductor device includes; a substrate comprising an active cell region, an edge terminal region surrounding the active cell region, and a peripheral region between the active cell region and the edge terminal region, a peripheral body diode region disposed on the substrate and disposed to extend to a portion of the active cell region in the peripheral region; a first body region spaced apart from the peripheral body diode region and disposed in the active cell region, a first gate electrode disposed on the peripheral body diode region in a portion of the active cell region, and a second gate electrode disposed on the first body region of the active cell region.

According to some aspects, a first pillar structure disposed within the substrate, disposed over a portion of the peripheral region and the active cell region, and disposed below the peripheral body diode region; and a second pillar structure extending from the first body region into the substrate and spaced apart from the first pillar structure, wherein the first pillar structure comprises: a first pillar region extending into the substrate from the peripheral body diode region in the peripheral region; and a second pillar region extending into the substrate from the peripheral body diode region in the active cell region.

According to some aspects, the peripheral body diode region comprises: a first peripheral body diode region disposed in the peripheral region; and a second peripheral body diode region extending from the first peripheral body diode region and extending below the first gate electrode.

According to some aspects, the first peripheral body diode region extends on the first pillar structure, and the second peripheral body diode region extends between the first gate electrode and the first pillar structure.

According to some aspects, the first pillar structure further comprises a third pillar region disposed between the first pillar region and the second pillar region below the peripheral body diode region, and connecting an upper part of the first pillar region and an upper part of the second pillar region.

According to some aspects, the first body region and the peripheral body diode region are spaced apart from each other, and the first body region is spaced apart from a second body region that is disposed within the substrate in the active cell region and disposed below the second gate electrode.

According to some aspects, the active cell region comprises a first active region including a recessed region and a second active region, the peripheral region comprises a first peripheral region and a second peripheral region, the first peripheral region comprises a first region within the recessed region and a second region disposed between the first active region and the edge terminal region, the second peripheral region is disposed between the second active region and the edge terminal region, wherein the second region comprises: a first sub-region extending in the first direction and disposed between the first active region and the edge terminal region; a second sub-region extending in a second direction intersecting the first direction, and being between the first region and the edge terminal region; and a third sub-region extending in the second direction, and disposed between the first sub-region and the second sub-region and between the first active region and the edge terminal region, and wherein the peripheral body diode region extends from the third sub-region of the second region to a portion of the first active region.

According to some aspects, the first region protrudes from the second sub-region of the second region, and the peripheral body diode region extends from the third sub-region to a distal end of the first region.

According to some aspects, the peripheral body diode region further extends from the second peripheral region to a portion of the second active region.

According to some aspects of the disclosure, a semiconductor device includes; a substrate, a first pillar structure within the substrate, a first gate electrode on the first pillar structure, a peripheral body diode region extending along a first direction on the first pillar structure and comprising a first peripheral body diode region and a second peripheral body diode region between the first gate electrode and the first pillar structure, a second gate electrode on the substrate disposed to be spaced apart from the first gate electrode, a first body region disposed within the substrate below the second gate electrode and spaced apart from the peripheral body diode region along the first direction, and a second pillar structure extending within the substrate from the first body region and being below the second gate electrode, wherein the first pillar structure comprises, a first pillar region extending from the first peripheral body diode region into the substrate, a second pillar region extending from the second peripheral body diode region into the substrate, and a third pillar region disposed between the first pillar region and the second pillar region below the peripheral body diode region, and connecting an upper part of the first pillar region and an upper part of the second pillar region.

According to some aspects, a second body region disposed within the substrate below the second gate electrode and spaced apart from the first body region along the first direction, and a third pillar structure extending within the substrate from the second body region, wherein the second pillar structure and the third pillar structure are spaced apart from each other along the first direction.

Aspects of the disclosure are not limited to those mentioned above and other objects and advantages of the disclosure that have not been mentioned can be understood by the following description and will be more clearly understood according to embodiments of the disclosure. In addition, it will be readily understood that the objects and advantages of the disclosure can be realized by the means and combinations thereof set forth in the claims.

In addition to the contents described above, specific effects of the present disclosure will be described together while describing the following specific details for carrying out the present disclosure.

### BRIEF DESCRIPTION OF THE DRAWINGS

FIGS. 1a, 1b, and 1c are plan views for describing a semiconductor device in accordance with an embodiment of the present disclosure.

FIG. 2 is an enlarged view of region M in FIGS. 1a and 1b.

FIG. 3 is a cross-sectional view taken along line A-A′ of FIGS. 1a, 1b, and 1c.

FIG. 4 is a cross-sectional view taken along line B-B′ in FIG. 1b.

FIG. 5 is a plot for describing the effects of the semiconductor device in accordance with an embodiment of the present disclosure.

### DETAILED DESCRIPTION OF THE PREFERRED EMBODIMENTS

The terms or words used in the disclosure and the claims should not be construed as limited to their ordinary or lexical meanings. They should be construed as the meaning and concept in line with the technical idea of the disclosure based on the principle that the inventor can define the concept of terms or words in order to describe his/her own inventive concept in the best possible way. Further, since the embodiment described herein and the configurations illustrated in the drawings are merely one embodiment in which the disclosure is realized and do not represent all the technical ideas of the disclosure, it should be understood that there may be various equivalents, variations, and applicable examples that can replace them at the time of filing this application.

Although terms such as first, second, A, B, etc. used in the description and the claims may be used to describe various components, the components should not be limited by these terms. These terms are only used to differentiate one component from another. For example, a first component may be referred to as a second component, and similarly, a second component may be referred to as a first component, without departing from the scope of the disclosure. The term ‘and/or’ includes a combination of a plurality of related listed items or any item of the plurality of related listed items.

The terms used in the description and the claims are merely used to describe particular embodiments and are not intended to limit the disclosure. Singular forms are intended to include plural forms unless the context clearly indicates otherwise. In the application, terms such as “comprise,” “comprise,” “have,” etc. should be understood as not precluding the possibility of existence or addition of features, numbers, steps, operations, components, parts, or combinations thereof described herein.

Unless otherwise defined, the phrases “A, B, or C,” “at least one of A, B, or C,” or “at least one of A, B, and C” may refer to only A, only B, only C, both A and B, both A and C, both B and C, all of A, B, and C, or any combination thereof.

Unless being defined otherwise, all terms used herein, including technical or scientific terms, have the same meaning as commonly understood by those skilled in the art to which the disclosure pertains.

Terms such as those defined in commonly used dictionaries should be construed as having a meaning consistent with the meaning in the context of the relevant art, and are not to be construed in an ideal or excessively formal sense unless explicitly defined in the application. In addition, each configuration, procedure, process, method, or the like included in each embodiment of the disclosure may be shared to the extent that they are not technically contradictory to each other.

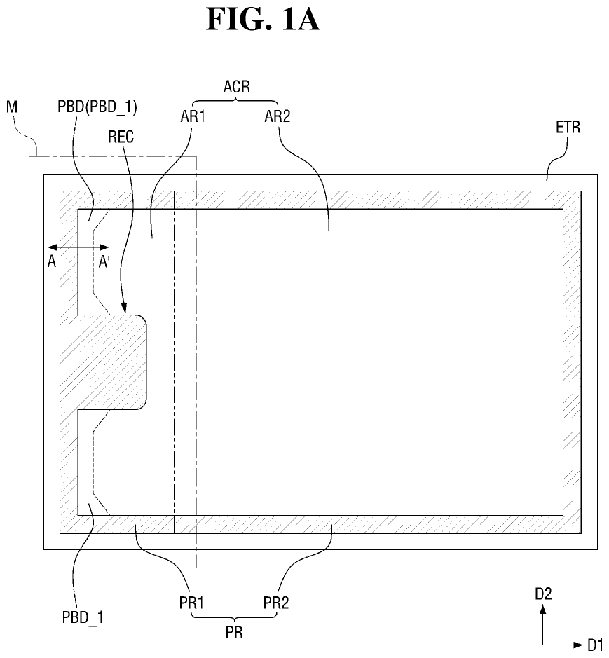

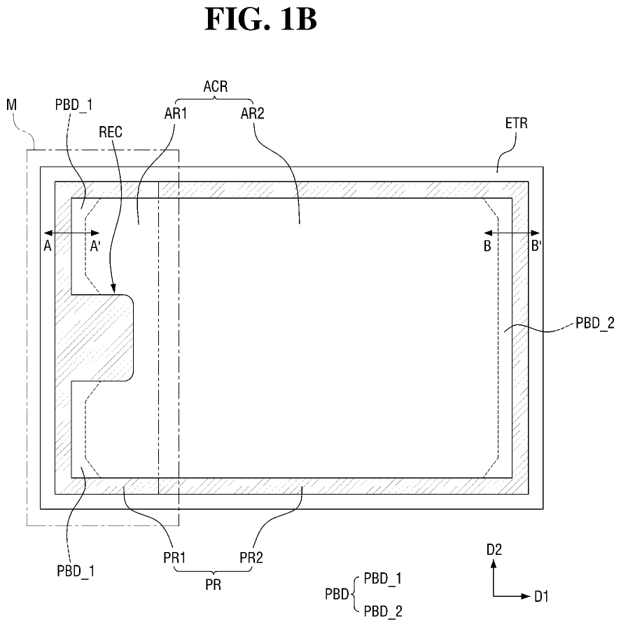

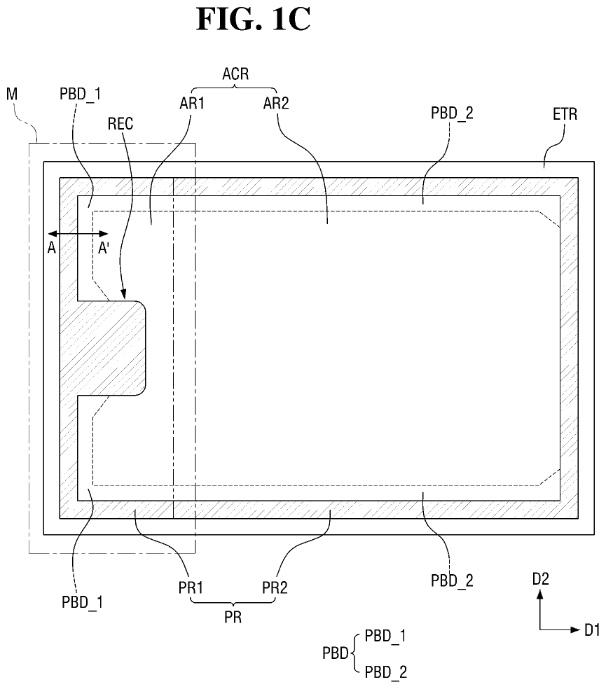

Hereinafter, a semiconductor device in accordance with an embodiment of the present disclosure will be described with reference to FIGS. 1a, 1b, 1c, 2, 3, 4, and 5.

FIGS. 1a, 1b, and 1c are plan views for describing a semiconductor device in accordance with an embodiment of the present disclosure.

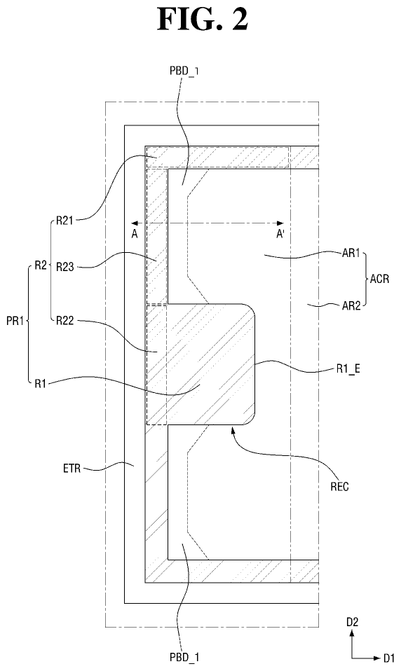

FIG. 2 is an enlarged view of region M in FIGS. 1a and 1b.

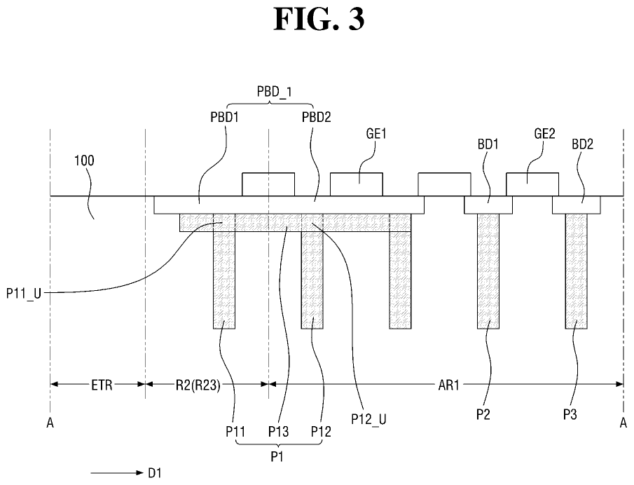

Referring to FIGS. 1a, 1b, 1c, and 2, a semiconductor device in accordance with an embodiment of the present disclosure may include a substrate (100 in FIG. 3), an active cell region ACR, an edge terminal region ETR, and a peripheral region PR.

The active cell region ACR may be a region on the substrate. The active cell region ACR may include a first active region AR1 and a second active region AR2. The first active region AR1 may include a recessed region REC. The recessed region REC may be a region in which a portion of the first active region AR1 is recessed.

The edge terminal region ETR may surround the active cell region ACR on the substrate.

The peripheral region PR may be a region between the active cell region ACR and the edge terminal region ETR. The peripheral region PR may include a first peripheral region PR1 and a second peripheral region PR2 on the substrate.

The first peripheral region PR1 may be a partial region of the peripheral region PR, disposed between the first active region AR1 and the edge terminal region ETR. The first peripheral region PR1 may include a first region R1 and a second region R2.

The first region R1 may be a partial region of the first peripheral region PR1, disposed within the recessed region REC. The first region R1 may protrude from the second region R2.

The second region R2 may be the remaining region of the first peripheral region PR1, disposed between the first active region AR1 and the edge terminal region ETR. The second region R2 may include a first sub-region R21, a second sub-region R22, and a third sub-region R23. The first sub-region R21 of the second region R2 may extend in a first direction D1 between the first active region AR1 and the edge terminal region ETR. The second sub-region R22 of the second region R2 may extend in a second direction D2 between the first region R1 and the edge terminal region ETR. The first direction D1 and the second direction D2 may be directions that intersect each other. The third sub-region R23 of the second region R2 may be a region extending in the second direction D2 between the first sub-region R21 and the second sub-region R22. The third sub-region R23 of the second region R2 may extend in the second direction D2 between the first active region AR1 and the edge terminal region ETR. The third sub-region R23 of the second region R2 may not overlap the first region R1 on the basis of the first direction D1. The third sub-region R23 of the second region R2 may be non-overlapping with the first region R1 along the first direction D1.

The first region R1 may protrude from the second sub-region R22 of the second region R2 along the first direction D1.

The second peripheral region PR2 may be the remaining region of the peripheral region PR, disposed between the second active region AR2 and the edge terminal region ETR.

The semiconductor device in accordance with an embodiment of the present disclosure may include a peripheral body diode region PBD extending from the peripheral region PR to a portion of the active cell region ACR. A portion of the peripheral body diode region PBD may be disposed in the peripheral region PR, and the rest of the peripheral body diode region PBD may be disposed in the active cell region ACR.

According to embodiments, the peripheral body diode region PBD may include only a first body diode region PBD_1, or may include a first body diode region PBD_1 and a second body diode region PBD_2.

The first body diode region PBD_1 may extend from the first peripheral region PR1 to a portion of the first active region AR1. The second body diode region PBD_2 may extend from the second peripheral region PR2 to a portion of the second active region AR2.

FIG. 3 is a cross-sectional view taken along line A-A′ of FIGS. 1a, 1b, and 1c.

Referring to FIGS. 1a, 1b, 1c, 2, and 3, the semiconductor device in accordance with an embodiment of the present disclosure may include a peripheral body diode region PBD, a first gate electrode GE1, a second gate electrode GE2, a first pillar structure P1, a second pillar structure P2, a third pillar structure P3, a first body region BD1, and a second body region BD2.

The substrate 100 may be, for example, bulk silicon or silicon-on-insulator (SOI). Alternatively, the substrate 100 may be a silicon substrate, or may include other materials, for example, silicon germanium, indium antimonide, lead telluride, indium arsenide, indium phosphide, gallium arsenide, or gallium antimonide. Or the substrate 100 may have an epitaxial layer (e.g., an n-type epitaxial layer) formed on a base substrate.

The first gate electrode GE1 and the second gate electrode GE2 may be disposed on the substrate 100. The first gate electrode GE1 and the second gate electrode GE2 may be disposed in the first active region AR1. The first gate electrode GE1 and the second gate electrode GE2 may be disposed to be spaced apart from each other.

The first gate electrode GE1 may be disposed on the first body diode region PBD_1 in a portion of the active cell region ACR. The first gate electrode GE1 may be disposed on the first body diode region PBD_1 (e.g., the second peripheral body diode region PBD2) in the first active region AR1. The first gate electrode GE1 may be disposed on the first pillar structure P1.

The second gate electrode GE2 may be disposed on the first body region BD1 and the second body region BD2 in the first active region AR1.

The peripheral body diode region PBD may be disposed on the substrate 100 and may be disposed to extend from the peripheral region PR to a portion of the active cell region ACR. The peripheral body diode region PBD may include a first body diode region PBD_1. In some embodiments, the peripheral body diode region PBD may include a first body diode region PBD_1 and a second body diode region PBD_2.

The first body diode region PBD_1 may extend from the second region R2 of the first peripheral region PR1 to a portion of the first active region AR1. The first body diode region PBD_1 may extend from the third sub-region R23 of the second region R2 to a portion of the first active region AR1. The first body diode region PBD_1 may be a partial region of the substrate 100 doped with p-type impurities or n-type impurities. The first body diode region PBD_1 may extend on the first pillar structure P1.

The first body diode region PBD_1 may include a first peripheral body diode region PBD1 and a second peripheral body diode region PBD2.

The first peripheral body diode region PBD1 may be disposed in the second region R2 of the first peripheral region PR1. The first peripheral body diode region PBD1 may be disposed in the third sub-region R23 of the second region R2. The first peripheral body diode region PBD1 may extend on the first pillar structure P1.

The second peripheral body diode region PBD2 may be a region connected to the first peripheral body diode region PBD1. The second peripheral body diode region PBD2 may extend from the first peripheral body diode region PBD1 to a portion of the first active region AR1. The second peripheral body diode region PBD2 may extend from the first peripheral body diode region PBD1 and may extend below the first gate electrode GE1. The second peripheral body diode region PBD2 may extend between the first gate electrode GE1 and the first pillar structure P1.

In some embodiments, the second peripheral body diode region PBD2 may extend from the first peripheral body diode region PBD1 to a distal end R1_E of the first region R1.

The first pillar structure P1 may be disposed within the substrate 100 and may be disposed over a portion of the second region R2 and the first active region AR1. The first pillar structure P1 may be disposed within the substrate 100 while overlapping the first body diode region PBD_1. The first pillar structure P1 may be disposed below the first body diode region PBD_1. The first pillar structure P1 may be a region doped with p-type impurities or n-type impurities.

The first pillar structure P1 may include a first pillar region P11, a second pillar region P12, and a third pillar region P13.

The first pillar region P11 may extend into the substrate 100 from the first peripheral body diode region PBD1 in the second region R2. The second pillar region P12 may extend into the substrate 100 from the second peripheral body diode region PBD2 in the first active region AR1. The third pillar region P13 may be disposed between the first pillar region P11 and the second pillar region P12, below the first body diode region PBD_1. The third pillar region P13 may connect the upper part P11_U of the first pillar region P11 and the upper part P12_U of the second pillar region P12 with each other. The third pillar region P13 may further extend along the first body diode region PBD_1, below the first body diode region PBD_1. The third pillar region P13 may extend within the substrate 100 along a direction intersecting the direction in which each of the first pillar region P11 and the second pillar region P12 extends within the substrate 100. The third pillar region P13 may connect the upper part P11_U of the first pillar region P11 and the upper part P12_U of the second pillar region P12 with each other while extending from the second region R2 to a portion of the first active region AR1.

The second pillar structure P2 may be disposed within the substrate 100 and may be disposed to be spaced apart from the first pillar structure P1 in the first active region AR1. The second pillar structure P2 may extend from the first body region BD1 into the substrate 100. The second pillar structure P2 may be a region doped with p-type impurities or n-type impurities.

The third pillar structure P3 may be disposed within the substrate 100 and may be disposed to be spaced apart from each of the first pillar structure P1 and the second pillar structure P2 in the first active region AR1. The third pillar structure P3 may extend from the second body region BD2 into the substrate 100. The third pillar structure P3 may be a region doped with p-type impurities or n-type impurities.

In some embodiments, a pillar structure may be further included in the edge terminal region ETR. The pillar structure in the edge terminal region ETR may be disposed to be spaced apart from the first pillar structure P1.

The first body region BD1 and the second body region BD2 may be disposed within the substrate 100 in the first active region AR1. The first body region BD1 and the second body region BD2 may be disposed below the second gate electrode GE2. The first body region BD1 and the second body region BD2 may be regions doped with p-type impurities or n-type impurities.

The first body diode region PBD_1, the first body region BD1, and the second body region BD2 may be disposed to be spaced apart from each other.

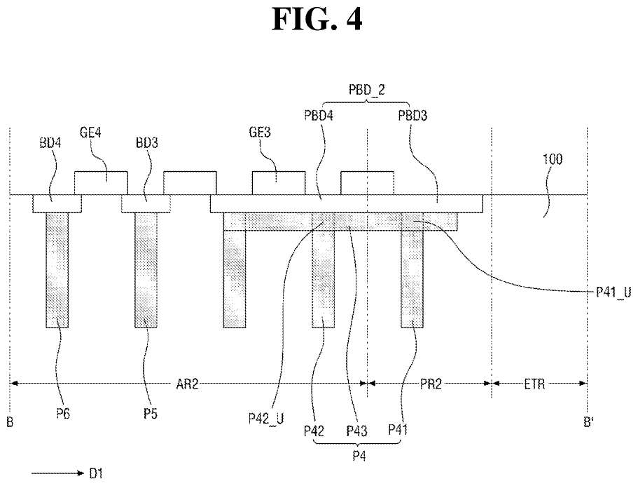

FIG. 4 is a cross-sectional view taken along line B-B′ in FIG. 1b. The description of FIG. 4 may be applied to the second body diode region PBD_2 of FIG. 1c. For clarity of description, those described previously will be simplified or omitted.

Referring to FIGS. 1b and 4, the semiconductor device in accordance with an embodiment of the present disclosure may include a peripheral body diode region PBD, a third gate electrode GE3, a fourth gate electrode GE4, a fourth pillar structure P4, a fifth pillar structure P5, a sixth pillar structure P6, a third body region BD3, and a fourth body region BD4.

The third gate electrode GE3 may be disposed on the second body diode region PBD_2 in a portion of the active cell region ACR. The third gate electrode GE3 may be disposed on the second body diode region PBD_2 (e.g., the third peripheral body diode region PBD3) in the second active region AR2. The third gate electrode GE3 may be disposed on the fourth pillar structure P4.

The fourth gate electrode GE2 may be disposed on the third body region BD3 and the fourth body region BD4 in the second active region AR2.

The second body diode region PBD_2 may extend from the second peripheral region PR2 to a portion of the second active region AR2. The second body diode region PBD_2 and the first body diode region PBD_1 may be partial regions of the substrate 100 doped with p-type impurities or n-type impurities. The second body diode region PBD_2 may extend on the fourth pillar structure P4.

The second body diode region PBD_2 may include a third peripheral body diode region PBD3 and a fourth peripheral body diode region PBD4.

The third peripheral body diode region PBD3 may be disposed in the second peripheral region PR2. The third peripheral body diode region PBD3 may extend on the fourth pillar structure P4.

The fourth peripheral body diode region PBD4 may be a region connected to the third peripheral body diode region PBD3. The fourth peripheral body diode region PBD4 may extend from the third peripheral body diode region PBD3 to a portion of the second active region AR2. The fourth peripheral body diode region PBD4 may extend from the third peripheral body diode region PBD3 and may extend below the third gate electrode GE3. The fourth peripheral body diode region PBD4 may extend between the third gate electrode GE3 and the fourth pillar structure P4.

The fourth pillar structure P4 may be disposed within the substrate 100 and may be disposed over a portion of the second peripheral region PR2 and the second active region AR2. The fourth pillar structure P4 may be disposed within the substrate 100 while overlapping the second body diode region PBD_2. The fourth pillar structure P4 may be disposed below the second body diode region PBD_2. The fourth pillar structure P4 may be a region doped with p-type impurities or n-type impurities.

The fourth pillar structure P4 may include a fourth pillar region P41, a fifth pillar region P42, and a sixth pillar region P43.

The fourth pillar region P41 may extend into the substrate 100 from the second peripheral body diode region PBD2 in the second peripheral region PR2. The fifth pillar region P42 may extend into the substrate 100 from the fourth peripheral body diode region PBD4 in the second active region AR2. The sixth pillar region P43 may be disposed between the fourth pillar region P41 and the fifth pillar region P42, below the second body diode region PBD_2. The sixth pillar region P43 may connect the upper part P41_U of the fourth pillar region P41 and the upper part P42_U of the fifth pillar region P42 with each other. The sixth pillar region P43 may further extend along the second body diode region PBD_2, below the second body diode region PBD_2. The sixth pillar region P43 may extend within the substrate 100 along a direction intersecting the direction in which each of the fourth pillar region P41 and the fifth pillar region P42 extends within the substrate 100. The sixth pillar region P43 may connect the upper part P41_U of the fourth pillar region P41 and the upper part P42_U of the fifth pillar region P42 with each other while extending from the second peripheral region PR2 to a portion of the second active region AR2,

The fifth pillar structure P5 may be disposed within the substrate 100 and may be disposed to be spaced apart from the fourth pillar structure P4 in the second active region AR2. The fifth pillar structure P5 may extend from the third body region BD3 into the substrate 100. The fifth pillar structure P5 may be a region doped with p-type impurities or n-type impurities.

The sixth pillar structure P6 may be disposed within the substrate 100 and may be disposed to be spaced apart from each of the fourth pillar structure P4 and the fifth pillar structure P5 in the second active region AR2. The sixth pillar structure P6 may extend from the fourth body region BD4 into the substrate 100. The sixth pillar structure P6 may be a region doped with p-type impurities or n-type impurities.

In some embodiments, a pillar structure may be further included in the edge terminal region ETR. The pillar structure in the edge terminal region ETR may be disposed to be spaced apart from the fourth pillar structure P4.

The third body region BD3 and the fourth body region BD4 may be disposed within the substrate 100 in the second active region AR2. The third body region BD3 and the fourth body region BD4 may be disposed below the fourth gate electrode GE4. The third body region BD3 and the fourth body region BD4 may be regions doped with p-type impurities or n-type impurities.

The second body diode region PBD_2, the third body region BD3, and fourth body region BD4 may be disposed to be spaced apart from each other.

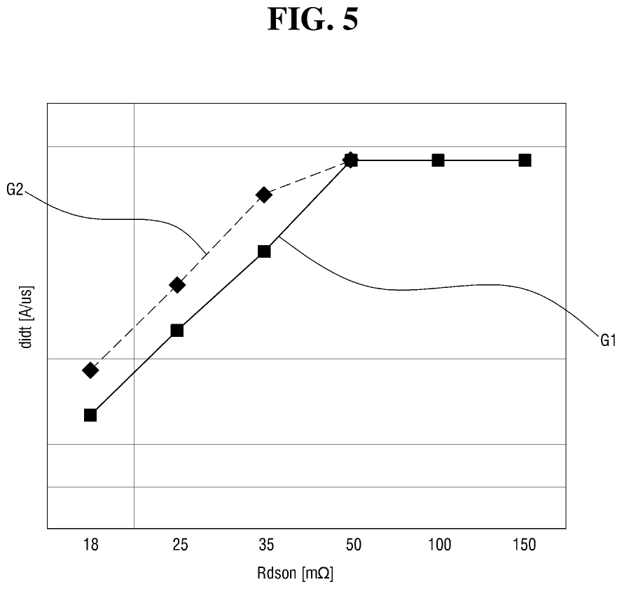

FIG. 5 is a plot for describing the effects of the semiconductor device in accordance with an embodiment of the present disclosure.

The horizontal axis of FIG. 5 may be the resistance (Rdson [mΩ]) when the transistor of the semiconductor device is turned on, and the vertical axis may be the amount of reverse current flowing per time (didt[A/μs]). The first graph G1 is a graph showing the amount of reverse current flowing per time in a semiconductor device in which the peripheral body diode region PBD does not extend from the peripheral region PR to a portion of the active cell region ACR. The second graph G2 is a graph showing the amount of reverse current flowing per time in a semiconductor device in which the peripheral body diode region PBD extends from the peripheral region PR to a portion of the active cell region ACR, as the semiconductor device in accordance with an embodiment of the present disclosure. Compared with the first graph G1, the second graph G2 shows that the amount of reverse current that can flow per time is higher within a certain range (e.g., 18 mΩ to 50 mΩ) even with the same resistance value. In other words, according to the semiconductor device in accordance with an embodiment of the present disclosure, by having the peripheral body diode region PBD extended from the peripheral region PR to a portion of the active cell region ACR, the range of accommodating the reverse current is increased compared with the case where the peripheral body diode region PBD is disposed only in the peripheral region PR, and the reliability of the semiconductor device can be secured. In addition, according to the semiconductor device in accordance with an embodiment of the present disclosure, by having the peripheral body diode region PBD extended from the peripheral region PR to a portion of the active cell region ACR, the range of accommodating the reverse current is increased compared with the case where the peripheral body diode region PBD is disposed only in the peripheral region PR, thereby reducing the possibility that a burnt region will occur in the semiconductor device.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims. It is therefore desired that the embodiments be considered in all respects as illustrative and not restrictive, reference being made to the appended claims rather than the foregoing description to indicate the scope of the disclosure.

What is claimed is:

1. A semiconductor device comprising:
a substrate;
an active cell region comprising a first active region including a recessed region and a second active region on the substrate;
an edge terminal region surrounding the active cell region on the substrate;
a first peripheral region comprising a first region within the recessed region and a second region disposed between the first active region and the edge terminal region on the substrate;
a second peripheral region disposed between the second active region and the edge terminal region; and
a first body diode region extending from the second region of the first peripheral region to a portion of the first active region,
wherein the first body diode region comprises:
a first peripheral body diode region disposed in the second region; and
a second peripheral body diode region extending from the first peripheral body diode region and extending below a first gate electrode disposed on the substrate in the first active region.

2. The semiconductor device of claim 1, comprising:
a first pillar structure disposed within the substrate, disposed over a portion of the second region and the first active region, and disposed below the first body diode region; and
a second pillar structure disposed within the substrate and disposed to be spaced apart from the first pillar structure in the first active region,
wherein the first pillar structure comprises:
a first pillar region extending into the substrate from the first peripheral body diode region in the second region; and
a second pillar region extending into the substrate from the second peripheral body diode region in the first active region, and
the second pillar structure extends into the substrate from a first body region below a second gate electrode disposed on the substrate in the first active region.

3. The semiconductor device of claim 2, wherein the first peripheral body diode region extends on the first pillar structure, and
the second peripheral body diode region extends between the first gate electrode and the first pillar structure.

4. The semiconductor device of claim 2, wherein the first pillar structure further comprises a third pillar region disposed between the first pillar region and the second pillar region below the first body diode region, and connecting an upper part of the first pillar region and an upper part of the second pillar region.

5. The semiconductor device of claim 2, wherein the first body region and the first body diode region are spaced apart from each other, and
the first body region is spaced apart from a second body region that is disposed within the substrate in the first active region and disposed below the second gate electrode.

6. The semiconductor device of claim 1, wherein the second region comprises:
a first sub-region extending in a first direction and disposed between the first active region and the edge terminal region;
a second sub-region extending in a second direction intersecting the first direction, and being between the first region and the edge terminal region; and
a third sub-region extending in the second direction, and disposed between the first sub-region and the second sub-region and between the first active region and the edge terminal region, and
wherein the first body diode region extends from the third sub-region of the second region to a portion of the first active region, and
the first peripheral body diode region is disposed in the third sub-region.

7. The semiconductor device of claim 6, wherein the third sub-region does not overlap the first region along the first direction.

8. The semiconductor device of claim 1, wherein the first region protrudes along a first direction from the second region, and
the second peripheral body diode region extends to a distal end of the first region.

9. The semiconductor device of claim 1, further comprising:
a second body diode region extending from the second peripheral region to a portion of the second active region.

10. A semiconductor device comprising:
a substrate comprising an active cell region, an edge terminal region surrounding the active cell region, and a peripheral region between the active cell region and the edge terminal region;
a peripheral body diode region disposed on the substrate and disposed to extend to a portion of the active cell region in the peripheral region;
a first body region spaced apart from the peripheral body diode region and disposed in the active cell region;
a first gate electrode disposed on the peripheral body diode region in a portion of the active cell region; and
a second gate electrode disposed on the first body region of the active cell region.

11. The semiconductor device of claim 10, comprising:
a first pillar structure disposed within the substrate, disposed over a portion of the peripheral region and the active cell region, and disposed below the peripheral body diode region; and
a second pillar structure extending from the first body region into the substrate and spaced apart from the first pillar structure,
wherein the first pillar structure comprises:
a first pillar region extending into the substrate from the peripheral body diode region in the peripheral region; and
a second pillar region extending into the substrate from the peripheral body diode region in the active cell region.

12. The semiconductor device of claim 11, wherein the peripheral body diode region comprises:
a first peripheral body diode region disposed in the peripheral region; and
a second peripheral body diode region extending from the first peripheral body diode region and extending below the first gate electrode.

13. The semiconductor device of claim 12, wherein the first peripheral body diode region extends on the first pillar structure, and
the second peripheral body diode region extends between the first gate electrode and the first pillar structure.

14. The semiconductor device of claim 11, wherein the first pillar structure further comprises a third pillar region disposed between the first pillar region and the second pillar region below the peripheral body diode region, and connecting an upper part of the first pillar region and an upper part of the second pillar region.

15. The semiconductor device of claim 10,
wherein the first body region and the peripheral body diode region are spaced apart from each other, and
the first body region is spaced apart from a second body region that is disposed within the substrate in the active cell region and disposed below the second gate electrode.

16. The semiconductor device of claim 10, wherein the active cell region comprises a first active region including a recessed region and a second active region,
the peripheral region comprises a first peripheral region and a second peripheral region,
the first peripheral region comprises a first region within the recessed region and a second region disposed between the first active region and the edge terminal region,
the second peripheral region is disposed between the second active region and the edge terminal region,
wherein the second region comprises:
a first sub-region extending in the first direction and disposed between the first active region and the edge terminal region;
a second sub-region extending in a second direction intersecting the first direction, and being between the first region and the edge terminal region; and
a third sub-region extending in the second direction, and disposed between the first sub-region and the second sub-region and between the first active region and the edge terminal region, and
wherein the peripheral body diode region extends from the third sub-region of the second region to a portion of the first active region.

17. The semiconductor device of claim 16, wherein the first region protrudes from the second sub-region of the second region, and
the peripheral body diode region extends from the third sub-region to a distal end of the first region.

18. The semiconductor device of claim 16, wherein the peripheral body diode region further extends from the second peripheral region to a portion of the second active region.

19. A semiconductor device comprising:
a substrate;
a first pillar structure within the substrate;
a first gate electrode on the first pillar structure;
a peripheral body diode region extending along a first direction on the first pillar structure and comprising a first peripheral body diode region and a second peripheral body diode region between the first gate electrode and the first pillar structure;
a second gate electrode on the substrate disposed to be spaced apart from the first gate electrode;
a first body region disposed within the substrate below the second gate electrode and spaced apart from the peripheral body diode region along the first direction; and
a second pillar structure extending within the substrate from the first body region and being below the second gate electrode,
wherein the first pillar structure comprises:
a first pillar region extending from the first peripheral body diode region into the substrate;
a second pillar region extending from the second peripheral body diode region into the substrate; and
a third pillar region disposed between the first pillar region and the second pillar region below the peripheral body diode region, and connecting an upper part of the first pillar region and an upper part of the second pillar region.

20. The semiconductor device of claim 19, further comprising:
a second body region disposed within the substrate below the second gate electrode and spaced apart from the first body region along the first direction; and
a third pillar structure extending within the substrate from the second body region,
wherein the second pillar structure and the third pillar structure are spaced apart from each other along the first direction.
